(19) United States
(12) Patent Application Publication
(10) Pub. No.: US 2010/0180941 A1
(43) Pub. Date: Jul. 22, 2010

(54) ANTIREFLECTION FILM OF SOLAR CELL, SOLAR CELL, AND METHOD OF MANUFACTURING SOLAR CELL

(75) Inventors: JungWook Lim, Daejeon-City (KR); Sun Jin Yun, Daejeon-City (KR); Hyun Tak Kim, Daejeon-City (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon-city (KR)

(21) Appl. No.: 12/506,187

(22) Filed: Jul. 20, 2009

(30) Foreign Application Priority Data
Sep. 8, 2008 (KR) 10-2008-0088479
Dec. 10, 2008 (KR) 10-2008-0125326

(51) Int. Cl. H01L 31/0232; H01L 31/00; H01L 31/18

(52) U.S. Cl. 136/256; 438/72; 257/E31.127

(57) ABSTRACT

Provided are an antireflection film of a solar cell, the solar cell, and a method of manufacturing the solar cell. The antireflection film of a solar cell includes a low dielectric film formed of a material having a first dielectric constant; a high dielectric film formed of a material having a second dielectric constant higher than the first dielectric constant; and a gradient layer disposed between the low dielectric film and the high dielectric film, and formed so as to gradually increase a dielectric constant from the first dielectric constant to the second dielectric constant. According to the present invention, light absorption efficiency of a solar cell can be increased.

### CROSS-REFERENCE TO RELATED PATENT APPLICATION

This application claims the benefit of Korean Patent Application Nos. 10-2008-0088479, filed on Sep. 8, 2008 and 10-2008-0125326, filed on Dec. 10, 2008, in the Korean Intellectual Property Office, the disclosure of which is incorporated herein in its entirety by reference.

### BACKGROUND OF THE INVENTION

1. Field of the Invention

The present invention relates to an antireflection film of a solar cell, the solar cell, and a method of manufacturing the solar cell, and more particularly, to an antireflection film of a solar cell, the solar cell, and a method of manufacturing the solar cell which can increase light absorption efficiency of the solar cell.

2. Description of the Related Art

Recently, fossil fuels are being depleted and global environment pollution is getting worse due to the use of fossil fuels.

Thus, there is an immediate need to find alternative sources of energy. The need for clean, renewable energy that can replace fossil fuels has increased, and the best renewable energy is solar light since solar light is available as long as the sun and the earth exist and does not generate air pollution.

Solar cells convert light into electricity by using solar light and obtain power through a process called the photovoltaic effect. That is, a p-type semiconductor that conducts by using holes and an n-type semiconductor that conducts by using electrons are bonded together, and electrons, holes, and charges are generated due to the absorption of photonic energy and thus, a current flows in an electric circuit. An output of a solar cell is obtained by multiplying a short circuit current I_{sc} and an open circuit voltage V_{oc}. Increased conversion efficiency, with regard to how much of the light from the sun is converted into electricity, should increase a short circuit current or an open circuit voltage or increase a fill factor (FF) which represents how closely a curve of an output current voltage approximates a square (I_{sc}×V_{oc}).

The method of increasing efficiency so as to increase a short circuit current depends on how much light is absorbed by a light absorbing layer of a solar cell and how much light is not reflected by the surface of the light absorbing layer. Accordingly, a thin film solar cell uses a method of allowing as much light as possible to reach a light absorbing layer by depositing an antireflection film on a glass substrate, and minimizes an area of an opaque front electrode. The front electrode uses a transparent conducting oxide (TCO) and the antireflection film uses a silicon nitride film or a titanium-silicon oxide film in order to prevent reflection and increase efficiency. However, it is not enough to ensure an antireflection characteristic over a broadband wavelength or an antireflection characteristic with respect to various incident angles.

To ensure the antireflection characteristic with respect to various incident angles, a method of decreasing the amount of reflection by making a front face of a transparent electrode or a silicon wafer uneven by etching with an alkali solution, is proposed, and this method is called texturing. However, in a polycrystal silicon wafer, surface texturing is not uniform due to differences in an etching speed according to a crystal face of the wafer, thus a decrease in the amount of reflection as a result of the texturing was not significant. Efforts to solve this problem have been made in a related field, and an optical trapping layer has recently been made of polymer by using a cross-linking structure. However, it is yet unknown how effective this is as an antireflection solution for thin film silicon solar cells, and it is not enough to ensure an antireflection characteristic with respect to a broadband wavelength. Texturing may be performed on a rear electrode in order to increase the reflective ability of a rear face of the transparent electrode or the silicon wafer. However, when the rear electrode is a metal electrode, the metal electrode partially absorbs light, and thus it is not that helpful.

Recently, a method of manufacturing an antireflection film with respect to a glass substrate has been developed. The antireflection film having a refractivity gradient is formed of SiO₂ and TiO₂ in a laminated structure, that is, in a multi-layered structure, by using a sputtering method. However, the antireflection film is formed as a mixed-layer, that is not a form of a compound of SiO₂ and TiO₂, and thus the manufacturing process is very complicated, and the antireflection layer is only limited to a glass substrate.

### SUMMARY OF THE INVENTION

The present invention provides an antireflection film of a solar cell, the solar cell, and a method of manufacturing the solar cell which can prevent as much reflection as possible with respect to a broadband wavelength and to solar light having various incident angles, by depositing a mixed layer of a high dielectric film and a low dielectric film while controlling the refractivity and thickness of the mixed layer.

The present invention also provides a solar cell which can increase efficiency by trapping solar light effectively by disposing an antireflection film and a highly reflective film.

According to an aspect of the present invention, there is provided an antireflection film of a solar cell, the antireflection film including: a low dielectric film formed of a material having a first dielectric constant; a high dielectric film formed of a material having a second dielectric constant higher than the first dielectric constant; and a gradient layer disposed between the low dielectric film and the high dielectric film, and formed so as to gradually increase a dielectric constant from the first dielectric constant to the second dielectric constant.

According to another aspect of the present invention, there is provided a solar cell including: a transparent substrate allowing light to pass through; an antireflection film formed under the transparent substrate so as to increase a dielectric constant as the distance between the transmission substrate and the antireflection film increases; and a light absorbing layer formed under the antireflection film converting light that has passed through the antireflection film into electric energy.

According to another aspect of the present invention, there is provided a solar cell including: a transparent substrate allowing light to pass through; an antireflection film formed under the transparent substrate so as to increase a dielectric constant as the distance between the transparent substrate and the antireflection film increases; a light absorbing layer formed under the antireflection film and converting light that has passed through the antireflection film into electric energy; and a highly reflective film formed under the light absorbing layer and reflecting light that has passed without being converted in the light absorbing layer to the light absorbing layer again.

According to another aspect of the present invention, there is provided a method of manufacturing a solar cell, the method including: forming a substrate; depositing an antireflection film formed so as to increase a dielectric constant as the distance between the substrate and the antireflection film increases on the substrate; and connecting an electrode to the antireflection film, and depositing a light absorbing layer connected to the electrode and generating an electric energy.

### BRIEF DESCRIPTION OF THE DRAWINGS

The above and other features and advantages of the present invention will become more apparent by describing in detail exemplary embodiments thereof with reference to the attached drawings in which:

FIGS. 1A and 1B show a structure of a solar cell according to an embodiment of the present invention;

FIG. 2 is a flowchart of a method of manufacturing a solar cell according to an embodiment of the present invention;

FIG. 3 shows a structure of a solar cell according to an embodiment of the present invention;

FIG. 4 shows a structure of a highly reflective film of a solar cell according to another embodiment of the present invention;

FIG. 5 shows a structure of a highly reflective film of a solar cell according to another embodiment of the present invention;

FIG. 6 is a graph showing variations in reflective ability according to wavelengths, when an antireflection film is formed in a single-layered structure and in a multi-layered structure; and

FIG. 7 shows an example in which an antireflection film of a solar cell is used in crystal silicon or a polycrystal silicon-germanium thin film solar cell, according to an embodiment of the present invention.

### DETAILED DESCRIPTION OF THE INVENTION

The present invention will now be described more fully with reference to the accompanying drawings, in which exemplary embodiments of the invention are shown. In the description, the detailed descriptions of well-known functions and structures may be omitted so as not to hinder the understanding of the present invention.

When one element “includes” one component in the present specification, it means that the element further includes another element instead of excluding another element as long as description to the contrary does not exist.

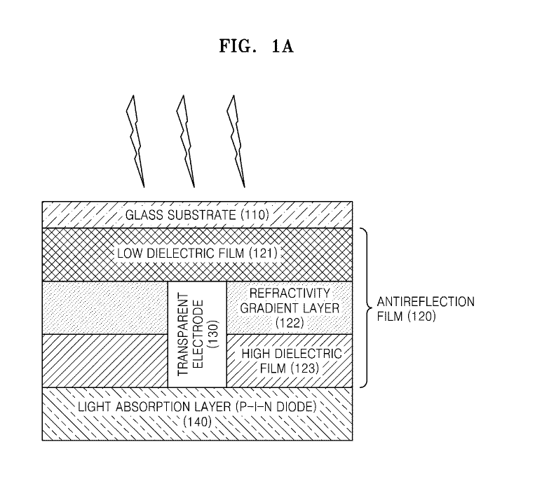

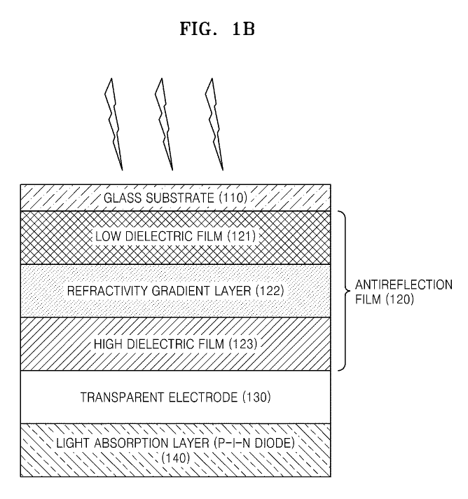

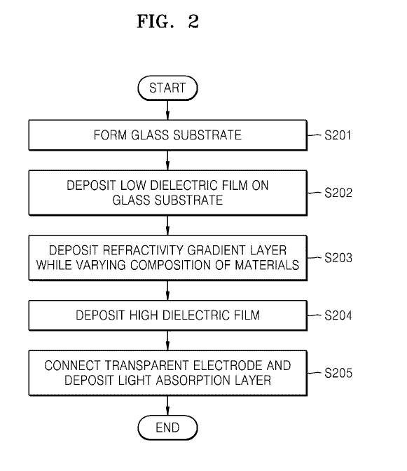

FIGS. 1A and 1B show a structure of a solar cell according to an embodiment of the present invention. FIG. 2 is a flowchart of a method of manufacturing a solar cell according to an embodiment of the present invention.

Referring to FIGS. 1A and 1B, a solar cell according to the current embodiment includes a glass substrate 110, an antireflection film 120, a transparent electrode 130, and a light absorbing layer 140.

The glass substrate 110 allows incident light to pass therethrough, and the light absorbing layer 140 converts light that has passed through the glass substrate 110 and the antireflection film 120 into electric energy. The transparent electrode 130 connected to the light absorbing layer 140 allows electricity converted in the light absorbing layer 140 to flow.

The antireflection film 120 is disposed between the glass substrate 110 and the light absorbing layer 140 and lowers reflexibility with respect to incident light through the glass substrate 110. In the current embodiment, composition of materials for forming the antireflection film 120 is adjusted to have a refractivity gradient so that a dielectric constant increases as the distance between the glass substrate 110 and the antireflection film 120 increases.

In the current embodiment, first, the glass substrate 110 is formed (S201), and a low dielectric film 121 formed of materials having a low dielectric constant is deposited on the glass substrate 110 (S202). Then, a refractivity gradient layer 122, which has a refractivity gradient due to a gradual increase in a dielectric constant on the basis of the dielectric constant of the low dielectric film 121 while varying the composition of materials, is deposited (S203), and a high dielectric film 123 formed of materials having a high dielectric constant is deposited (S204). When the deposition of the antireflection film 120 is finished, the transparent electrode 130 is deposited on the entire surface of the antireflection film 120 or is patterned on the antireflection film 120, then the light absorbing layer 140 is deposited to be connected to the transparent electrode 130 (S205). The transparent electrode 130 may be formed to have various thicknesses of from about 20 nm to about 300 nm. The transparent electrode 130 may be patterned on the antireflection film 120 as shown in FIG. 1A, or may be deposited on the entire surface of the antireflection film 120 as shown in FIG. 1B.

In the current embodiment, the glass substrate 110 is used, but the antireflection film 120 may be deposited on a plastic substrate, a metal substrate, or the like, instead of on the glass substrate 110.

The low dielectric film 121 may include Al₂O₃, SiO₂, SiN, etc. that are each an oxide thin film or a nitride thin film having a low dielectric constant, for example, having a relative dielectric constant of less than 10.

The high dielectric film 123 may include TiO₂, ZrO₂, HfO₂, Ta₂O₅, ZnO, etc that are each an oxide thin film having a high dielectric constant, for example, having a relative dielectric constant of more than 10.

The refractivity gradient layer 122 may be formed to have a dielectric constant that gradually increases from the dielectric constant of the low dielectric film 121 to the high dielectric constant of the high dielectric film 123.

The antireflection film 120 may include an oxide thin film having a high dielectric constant, for example, TiO₂, ZrO₂, HfO₂, Ta₂O₅, ZnO, etc., and an oxide thin film or a nitride thin film having a low dielectric constant, for example, Al₂O₃, SiO₂, SiN, etc., in a compound type of a sub-monolayer so as to control the refractivity and thickness of the antireflection film 120. The deposition method uses a conventional atomic layer deposition method (or a plasma atomic layer deposition method), but may use a sol-gel method for mass production under different conditions. The deposition temperature may be less than 500°, because the deposition is performed on a silicon thin film solar cell as well as in a bulk-type silicon solar cell. Also, since the deposition method uses an atomic layer deposition method, a thin film solar cell is advantageous when manufacturing a large size antireflection thin film.

For example, an ATO (AlTiO) thin film may be formed of a TiO₂ high dielectric film (refractive index: 2.4 to 2.5) and an Al₂O₃ low dielectric film (refractive index: 1.6 to 1.7) by controlling the number of cycles of the atomic layer deposition method. In this case, the composition of Ti may be controlled by controlling the cycle ratio to control refractivity. As such, when the atomic layer deposition method is used, the composition of ATO may be freely changed in-situ during the deposition. Also, since the atomic layer deposition method is programmed in advance, the process is not stopped or a vacuum state is not broken. Thus successive deposition is possible as if all deposited at once.

An optical thickness is generally obtained by multiplying a thickness and refractivity, and refractivity close to 0 in relation to a desired wavelength may be obtained by controlling the optical thickness. When the antireflection film 120 is formed to have a refractivity gradient as described in the current embodiment, refractivity may be decreased in a longer wavelength band. Also, when the atomic layer deposition method is used, a refractivity gradient layer of which refractivity varies gradually from a low dielectric film to a high dielectric film in-situ may be easily manufactured.

In general, when the atomic layer deposition method is used, a thin film may be formed at a relatively low temperature of from about 100° to about 300°, and thus the antireflection film 120 may be formed on a glass substrate in the thin film solar cell. Furthermore, the antireflection film 120 may be formed on a plastic substrate requiring a process temperature of less than 150° in an organic solar cell.

The antireflection film 120 of the current embodiment may be used in various type of solar cells, such as a thin film solar cell formed of silicon, silicon-germanium, CuInGaSe (CIGS), CdTe, or the like, a GaAs-based compound solar cell, an organic solar cell, a dye sensitized solar cell (DSC), etc.

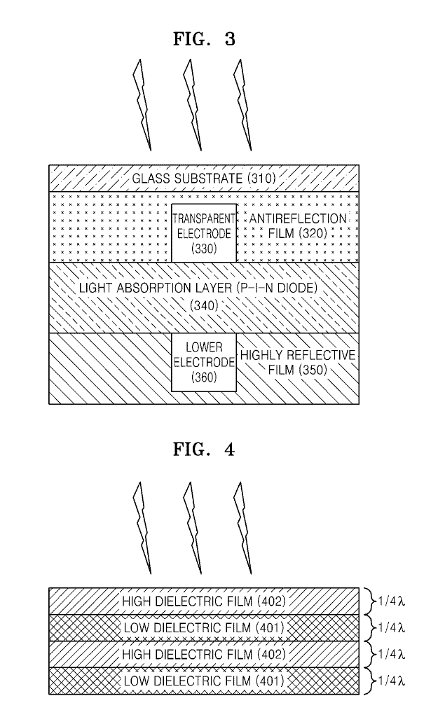

FIG. 3 shows a structure of a solar cell according to an embodiment of the present invention.

Referring to FIG. 3, a solar cell according to the current embodiment includes a glass substrate 310, an antireflection film 320, a transparent electrode 330, a light absorbing layer 340, a highly reflective film 350, and a lower electrode 360.

The glass substrate 310, the antireflection film 320, the transparent electrode 330, and the light absorbing layer 340 perform the same functions as the glass substrate 110, the antireflection film 120, the transparent electrode 130, and the light absorbing layer 140 of FIG. 1. However, in the current embodiment, the highly reflective film 350 is formed under the light absorbing layer 340, so that the highly reflective film 350 together with the antireflection film 320 can effectively trap solar light in the light absorbing layer 340 (p-i-n diode). In other words, a light trapping structure is realized.

In the light trapping structure of the current embodiment, a mixed layer of a high dielectric film and a low dielectric film is deposited on a front surface of the light absorbing layer 340 by controlling the refractivity and thickness of the mixed layer. Then, the antireflection film 320 having a refractivity gradient according to the mixture ratio is disposed to prevent as much reflection as possible with respect to a broadband wavelength and solar light having various incident angles. Also, the highly reflective film 350 is disposed on a rear face of the light absorbing layer 340, so that as much solar light as possible that has passed through the light absorbing layer 340 and has been transmitted to the rear face of the light absorbing layer 340 is reflected to trap the solar light in the light absorbing layer 340.

The transparent electrode 330 and the lower electrode 360 are respectively connected to an upper end portion and a lower end portion so as to allow current to flow to the light absorbing layer 340, thereby generating a photovoltaic effect in the light absorbing layer 340.

FIG. 4 shows a structure of a highly reflective film of a solar cell according to another embodiment of the present invention.

The highly reflective film according to the current embodiment has a structure in which a unit-layer structure including a low dielectric film 401 and a high dielectric film 402 is repeatedly deposited.

As in the current embodiment, when the low dielectric film 401 and the high dielectric film 402 are repeatedly disposed to a predetermined thickness (about a quarter of a wavelength (λ) of antireflection light), an extremely high reflection effect can be obtained. Also, as the number of repeated layers increases, reflection can be effectively performed in a wide wavelength band.

In the prior art, a metal electrode is used to form a highly reflective film, light is partially absorbed in the metal electrode, and also a transparent solar cell could not be realized due to an opaque property of a metal. On the other hand, in the current embodiment, by using the highly reflective film, absorption is effectively prevented in the highly reflective film, thereby realizing a transparent solar cell.

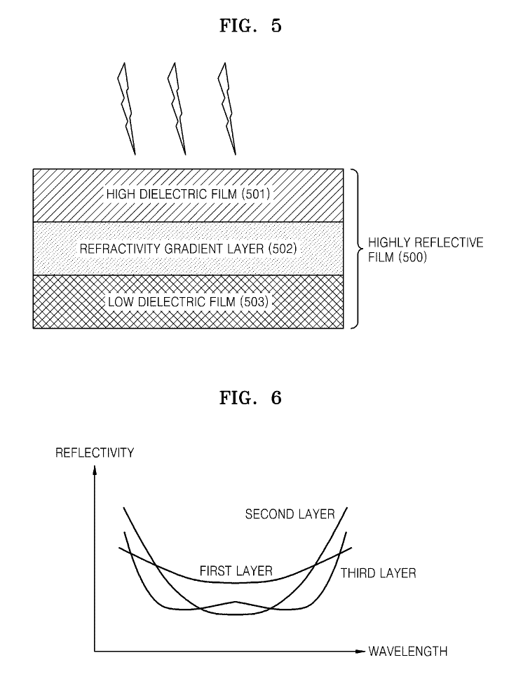

FIG. 5 shows a structure of a highly reflective film of a solar cell according to another embodiment of the present invention.

Referring to FIG. 5, a highly reflective film 500 has a reversed structure of the antireflection film 120 of FIG. 1, that is, a high dielectric film 501, a refractivity gradient layer 502, and a low dielectric film 503 may be sequentially deposited in an incident direction of solar light. The high dielectric film 501, the refractivity gradient layer 502, and the low dielectric film 503 may have the same functions as the high dielectric film 123, the refractivity gradient layer 122, and the low dielectric film 121 of FIG. 1. However, unlike the structure of the antireflection film 120, the high dielectric film 501, the refractivity gradient layer 502, and the low dielectric film 503 may be disposed in a reversed order on the basis of the incident direction of solar light so as to perform a function of effectively preventing absorption in the highly reflective film 500.

FIG. 6 is a graph showing variations in reflective ability according to wavelengths, when a single layer including compound of a high dielectric film and a low dielectric film, such as ATO, is employed as an antireflection film and when two dielectric films, each having different compositions, are formed as a multi-layered structure.

In general, solar light entering via a visible rays region and an infrared rays region has a low efficiency because light losses in terms of the infrared rays as well as in the visible rays are great. Accordingly, how effectively the reflection of light in such a long wavelength band is prevented is the key to increasing efficiency. Minimizing reflection by a blue region, that is an especially strong region in a visible rays layer is also another key. Also, since solar light is not necessarily incident vertically, reflection should be effectively blocked with respect to various incident angles.

Referring to FIG. 6, a low reflective ability can be obtained in a wider range when the antireflection film is formed as a multi-layered structure, for example, a double-, triple-layered structure, or the like, as compared to when the antireflection film is formed as a single-layered structure. In particular, a reflection film having a refractivity gradient with respect to various incident angles may be very effectively manufactured.

If a light absorbing layer of a solar cell is formed in a multi-junction structure of more than two layers, antireflection films for a wavelength band of the light absorbing layer may be inserted between the light absorbing layers, and an antireflection film allowing light of a desired wavelength band to effectively transmit to the light absorbing layer can be realized.

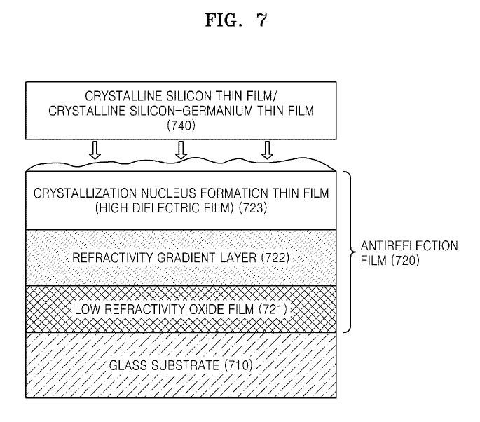

FIG. 7 shows an example in which an antireflection film of a solar cell is used in a crystal silicon or a polycrystal silicon-germanium thin film solar cell, according to an embodiment of the present invention.

Referring to FIG. 7, similarly to the previous embodiments, an antireflection film 720 includes a low dielectric film 721, a refractivity gradient layer 722, and a high dielectric film 723.

When the high dielectric film 723 is a crystal film grown at a temperature range of from about 150° to about 500°, the high dielectric film 723 hastens crystallization nucleus formation of a polysilicon thin film or a polysilicon-germanium thin film, and consequently can contribute to an increase in the absorption capability of the light absorbing layer 740.

Such a function of the high dielectric film 723 may be equally applied to all kinds of thin film solar cells using a polycrystal thin film or a microcrystalline thin film as a light absorbing layer. When the antireflection film 720 having a refractivity gradient is manufactured, a high dielectric film 823 formed of TiO₂, ZrO₂, Ta₂O₅, HfO₂, or the like is used as an uppermost layer, and such a thin film has a low crystallization temperature. Even when the high dielectric film 723 is deposited at a temperature of about 250°, the high dielectric film 723 may be crystallized, and a ZrO₂ crystalline thin film hastens crystallization of Si. When the high dielectric film 723 is deposited using plasma, the high dielectric film 723 may be crystallized at a temperature of 150°.

Accordingly, the antireflection film 720 functions to hasten crystallization of a light absorbing layer related to efficiency of a solar cell. Also, the antireflection film 720 and the highly reflective film according to the current embodiment which are insulators can insulate between electrodes or between a semiconductor layer and an electrode.

An antireflection film of a solar cell according to the present invention prevents solar light of a solar cell from losing light due to reflection by controlling optical thicknesses of a high dielectric film having a high refractivity and a low dielectric film having a low refractivity.

The antireflection film has a refractivity gradient due to the formation of a compound of a high dielectric film and a low dielectric film through an atomic layer deposition method, and thus, solar light incident at various incident angles can be effectively trapped. Also, the antireflection film is formed in a multi-layered structure to prevent reflection with respect to light of a wide wavelength band, and the antireflection film is advantageous when manufacturing a large size solar cell.

Furthermore, a high dielectric film of the antireflection film contributes to crystallization nucleus formation of silicon or silicon germanium, and also the antireflection film itself can effectively act as insulation between a semiconductor layer and an electrode. Also, the high dielectric film of the antireflection film enables a transparent thin film solar cell to be manufactured.

A solar cell according to the present invention can effectively increase conversion efficiency by trapping solar light in a light absorbing layer, and in particular, can maximize efficiency in a thin film solar cell field.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An antireflection film of a solar cell, the antireflection film comprising:
a low dielectric film formed of a material having a first dielectric constant;
a high dielectric film formed of a material having a second dielectric constant higher than the first dielectric constant; and
a gradient layer disposed between the low dielectric film and the high dielectric film, and formed so as to gradually increase a dielectric constant from the first dielectric constant to the second dielectric constant.

2. The antireflection film of claim 1, wherein relative dielectric constants of the first dielectric constant and the second dielectric constant are less than 10 and more than 10, respectively.

3. The antireflection film of claim 1, wherein the low dielectric film comprises at least one of Al₂O₃, SiO₂, SiN, and the high dielectric film comprises at least one of TiO₂, ZrO₂, HfO₂, Ta₂O₅, ZnO.

4. The antireflection film of claim 1, wherein the gradient layer is formed using at least one of an atomic layer deposition method, a plasma atomic layer deposition method, and a sol-gel method.

5. The antireflection film of claim 1, wherein the gradient layer is formed of a compound comprising a material having the first dielectric constant and a material having the second dielectric constant.

6. A solar cell comprising:
a transmission substrate allowing light to pass through;
an antireflection film formed under the transmission substrate so as to increase a dielectric constant as the distance between the transmission substrate and the antireflection film increases; and
a light absorbing layer formed under the antireflection film converting light that has passed through the antireflection film into electric energy.

7. The solar cell of claim 6, wherein the antireflection film comprises:
a low dielectric film formed of a material having a first dielectric constant;
a high dielectric film formed of a material having a second dielectric constant higher than the first dielectric constant; and
a gradient layer disposed between the low dielectric film and the high dielectric film, and formed so as to gradually increase a dielectric constant from the first dielectric constant to the second dielectric constant.

8. The solar cell of claim 6, wherein the low dielectric film comprises at least one of Al₂O₃, SiO₂, and SiN, and the high dielectric film comprises at least one of TiO₂, ZrO₂, HfO₂, Ta₂O₅, and ZnO.

9. The solar cell of claim 6 further comprising an electrode patterned on the antireflection film and connected to the light absorbing layer.

10. The solar cell of claim 6, wherein a wavelength region of light passing through the antireflection film is adjusted by controlling a thickness and refractivity of the antireflection film.

11. A solar cell comprising:
a transmission substrate allowing light to pass through;
an antireflection film formed under the transmission substrate so as to increase a dielectric constant as the distance between the transmission substrate and the antireflection film increases;
a light absorbing layer formed under the antireflection film and converting light that has passed through the antireflection film into electric energy; and
a highly reflective film formed under the light absorbing layer and reflecting light that has passed without being converted in the light absorbing layer to the light absorbing layer again.

12. The solar cell of claim 11, wherein the highly reflective film is formed by repeatedly stacking a unit-layer structure comprising a low dielectric film formed of a material having a first dielectric constant and a high dielectric film which is formed over the low dielectric film and is formed of a material having a second dielectric constant higher than the first dielectric constant.

13. The solar cell of claim 11, wherein the highly reflective film comprises a low dielectric film formed of a material having a first dielectric constant, a high dielectric film formed of a material having a second dielectric constant higher than the first dielectric constant, and a gradient layer disposed between the low dielectric film and the high dielectric film and formed so as to gradually increase a dielectric constant from the first dielectric constant to the second dielectric constant.

14. The solar cell of claim 11, wherein the antireflection film comprises a low dielectric film formed of a material having a first dielectric constant, a high dielectric film formed of a material having a second dielectric constant higher than the first dielectric constant, and a gradient layer disposed between the low dielectric film and the high dielectric film and formed so as to gradually increase a dielectric constant from the first dielectric constant to the second dielectric constant.

15. The solar cell of claim 13 or claim 14, wherein the low dielectric film comprises at least one of Al₂O₃, SiO₂, and SiN, and the high dielectric film comprises at least one of TiO₂, ZrO₂, HfO₂, Ta₂O₅, and ZnO.

16. The solar cell of claim 11, further comprising:
an upper electrode patterned on the antireflection film and connected to the light absorbing layer; and
a lower electrode patterned on the highly reflective film and connected to the light absorbing layer.

17. A method of manufacturing a solar cell, the method comprising:
forming a substrate;
depositing an antireflection film formed so as to increase a dielectric constant as the distance between the substrate and the antireflection film increases on the substrate; and
connecting an electrode to the antireflection film, and depositing a light absorbing layer connected to the electrode and generating an electric energy.

18. The method of claim 17, wherein the depositing of the antireflection film comprises:
depositing a low dielectric film formed of a material having a first dielectric constant on the substrate;
depositing a gradient layer of which a dielectric constant increases gradually on the basis of the first dielectric constant of the low dielectric film; and
depositing a high dielectric film formed of a material having a second dielectric constant higher than the first dielectric constant on the gradient layer.

19. The method of claim 17, wherein the depositing of the light absorbing layer comprises depositing the electrode on a front surface of the antireflection film or patterning the electrode on the antireflection film.

20. The solar cell of claim 13, wherein the low dielectric film comprises at least one of Al₂O₃, SiO₂, and SiN, and the high dielectric film comprises at least one of TiO₂, ZrO₂, HfO₂, Ta₂O₅, and ZnO.
